(19) United States
(12) Patent Application Publication
(10) Pub. No.: US 2017/0236980 A1
(43) Pub. Date: Aug. 17, 2017

(54) Optoelectronic Semiconductor Chip and Method for Producing the Same

(71) Applicant: OSRAM Opto Semiconductors GmbH, Regensburg (DE)

(72) Inventor: Guido Weiss, Regensburg (DE)

(21) Appl. No.: 15/502,473

(22) PCT Filed: Aug. 5, 2015
(86) PCT No.: PCT/EP2015/068096

§ 371 Date: Feb. 7, 2017

(30) Foreign Application Priority Data
Aug. 12, 2014 (DE) 10 2014 111 482.5

(51) Int. Cl. H01L 33/46; H01L 33/56; H01L 33/00

(52) U.S. Cl. CPC H01L 33/46; H01L 33/0079; H01L 33/56; H01L 2933/005; H01L 2933/0025

(57) ABSTRACT

An optoelectronic semiconductor chip and a method for producing the same are disclosed. In an embodiment an optoelectronic semiconductor chip includes a support substrate, a semiconductor layer sequence having a first semiconductor region of a first conductivity type, a second semiconductor region of a second conductivity type and an active layer arranged therebetween, and a mirror layer arranged between the support substrate and the semiconductor layer sequence. The chip further includes a dielectric encapsulation layer arranged at least partly between the semiconductor layer sequence and the support substrate and a transparent dielectric cover layer partially covering a region of the encapsulation layer, wherein the mirror layer and side flanks of the mirror layer are covered by an electrically conductive protective layer.

This patent application is a national phase filing under section 371 of PCT/EP2015/068096, filed Aug. 5, 2015, which claims the priority of German patent application 10 2014 111 482.5, filed Aug. 12, 2014, each of which is incorporated herein by reference in its entirety.

### TECHNICAL FIELD

The invention relates to an optoelectronic semiconductor chip and a method for producing the same.

### BACKGROUND

The present application particularly relates to a so-called thin film light emitting diode chip, in which the original growth substrate of the semiconductor layer sequence is removed and instead, the semiconductor layer sequence is connected to a support substrate, which is not the same as the growth substrate, on a side opposite the original growth substrate. For such a thin film light emitting diode chip, it is advantageous to have the side of the semiconductor layer sequence facing the support substrate provided with a mirror layer to deflect the radiation emitted in the direction of the support substrate toward the radiation exit surface, thereby increasing the radiation efficiency.

For the visible spectral range, silver is an especially suitable material for the mirror layer as it is highly reflective, wherein silver is, however, also sensitive to corrosion, particularly corrosion by moisture entering the semiconductor chip.

### SUMMARY OF THE INVENTION

Embodiments of the invention provide an improved optoelectronic semiconductor chip, which is especially well protected against the entry of moisture. Various other embodiments provide an advantageous method for producing the optoelectronic semiconductor chip.

According to at least one embodiment, the optoelectronic semiconductor chip comprises a support substrate and a semiconductor layer sequence, which contains a first semiconductor region of a first conductivity type, a second semiconductor region of a second conductivity type and an active layer arranged therebetween. The first semiconductor region may, for example, face the support substrate and preferably is a p-type semiconductor region. The second semiconductor region may, for example, face a radiation exit surface of the semiconductor chip and preferably is an n-type semiconductor region.

The semiconductor layer sequence of the optoelectronic semiconductor chip comprises a mesa structure. Thus, the lateral extension of the semiconductor layer sequence is smaller than the lateral extension of the support substrate. The mesa structure may be produced by means of a photolithographic process, in which the semiconductor layer sequence is partially removed to structure it into a desired shape and size. The manufacturing of the mesa structure may, for example, generate oblique side flanks.

The optoelectronic semiconductor chip preferably is a so-called thin film semiconductor chip, in which the original growth substrate is removed from the semiconductor layer sequence and the semiconductor layer sequence is connected to a support substrate on a side opposite the original growth substrate.

Between the support substrate and the semiconductor layer sequence, a mirror layer comprising or consisting of silver is advantageously arranged. Silver is particularly suitable as material for the mirror layer as silver has a high reflectance in the visible spectral range. The mirror layer may further form an electrical contact to the first semiconductor region.

Furthermore, the optoelectronic semiconductor chip comprises a dielectric encapsulation layer which particularly serves to protect the mirror layer. The dielectric encapsulation layer is partially arranged between the semiconductor layer sequence and the support substrate. In particular, the dielectric encapsulation layer extends from the side flanks of the semiconductor chip formed by the mesa structure to beneath the semiconductor layer. The dielectric encapsulation layer is arranged laterally next to the mirror layer and, advantageously, extends in a lateral direction into a region next to the mesa structure.

Furthermore, the optoelectronic semiconductor chip advantageously comprises a transparent dielectric cover layer, which at least partially covers part of the dielectric encapsulation layer arranged next to the mesa structure and the semiconductor layer sequence. Preferably, the transparent dielectric cover layer covers all otherwise exposed regions of the semiconductor layer sequence, in particular the side flanks of the semiconductor layer sequence. Furthermore, the transparent dielectric cover layer advantageously also covers the radiation exit surface of the semiconductor layer sequence that faces away from the support substrate, except for regions that are covered by an electrical contact layer such as a bond pad.

The cooperation of the encapsulation layer extending to beneath the semiconductor layer sequence and the cover layer covering exposed regions of the semiconductor layer sequence which are not adjacent to the encapsulation layer allows a particularly efficient protection of the semiconductor chip, and in particular the mirror layer, against environmental influences, in particular against the entry of moisture. Advantageously, the dielectric encapsulation layer is also suitable to prevent an undesired current injection into the adjacent region of the first semiconductor region. For example, part of the dielectric encapsulation layer is, in a vertical direction, opposite a contact, in particular a bond pad, on the radiation exit surface. In this case, it is advantageous if no current is injected into the region of the semiconductor layer sequence arranged beneath the contact, because the radiation generated in this region would otherwise at least partially be absorbed in the contact.

In an advantageous embodiment of the optoelectronic semiconductor chip, the mirror layer is covered by an electrically-conductive protective layer. The electrically conductive protective layer covers the mirror layer in particular on the side of the mirror layer that faces away from the semiconductor layer sequence.

Particularly preferably, the mirror layer, including its side flanks, is covered by the electrically conductive protective layer. In this case, the mirror layer is also encapsulated at the side flanks by the electrically conductive protective layer such as to be protected in a particularly efficient manner. The electrically conductive protective layer protects the mirror layer, in particular from the diffusion of components of adjacent layers into the mirror layer and vice versa. In particular, the electrically conductive protective layer prevents diffusion of silver from the mirror layer into regions arranged laterally next to the mirror layer and/or toward the layers subsequent to the support substrate. Further, the electrically conductive protective layer protects the mirror layer, in particular from oxidation.

The electrically conductive protective layer may in particular contain a transparent conductive oxide or consist thereof. Particularly preferably, the electrically conductive protective layer contains ZnO or consists thereof, as ZnO is particularly suitable as a protective layer for a silver layer.

In a preferred embodiment of the optoelectronic semiconductor chip, the dielectric encapsulation layer is an ALD layer, which means a layer produced by means of atomic layer deposition. This method allows for advantageously producing very dense layers with low defect density. An ALD layer therefore provides especially good protection against the entry of moisture.

Furthermore, the dielectric cover layer is preferably also at least partially designed as an ALD layer. The dielectric cover layer may, for example, comprise a first partial layer, which is an ALD layer. The first partial layer of the dielectric cover layer may have at least one further partial layer applied thereto, which does not necessarily have to be produced by means of an ALD method.

Forming the dielectric encapsulation layer and/or the dielectric cover layer designed as an ALD layer has the advantage that layers produced by means of ALD are particularly dense and therefore offer especially good protection against the entry of moisture.

The dielectric encapsulation layer preferably comprises an aluminum oxide, in particular Al₂O3. It has been found that aluminum oxide, in particular aluminum oxide applied by means of ALD, offers especially good protection against the entry of moisture and therefore protects the semiconductor chip and the mirror layer efficiently against corrosion. The dielectric encapsulation layer preferably has a thickness of between 5 nm and 100 nm.

The transparent dielectric cover layer preferably comprises an aluminum oxide, in particular Al₂O3, and/or a silicon oxide, in particular SiO₂. For example, the transparent dielectric cover layer may comprise a first partial layer made of an aluminum oxide, which layer is preferably produced by means of ALD, and a second partial layer made of a silicon oxide. The silicon oxide layer may also be produced by means of an ALD method or by means of a different coating method such as vapor deposition or sputtering.

In addition to or as an alternative to the silicon oxide layer, the transparent dielectric cover layer may comprise a silicon nitride layer, taking advantage of the fact that silicon nitride is, in the visible spectral range, at least partially absorbent. It is thus also possible to selectively adjust the brightness of the radiation emitted by the optoelectronic semiconductor chip by applying a silicon nitride layer having a suitable layer thickness.

In a preferred embodiment of the optoelectronic semiconductor chip, a contact is arranged on a radiation exit surface of the semiconductor chip, wherein part of the dielectric encapsulation layer is, in a vertical direction, opposite the contact to reduce a current injection into the region of the semiconductor layer sequence beneath the contact. This way, it is possible, by means of the electrically insulating properties of the encapsulation layer, to achieve a reduction in the generation of radiation beneath the contact and thus an absorption within the contact is reduced.

According to at least one embodiment, in the method for producing an optoelectronic semiconductor chip, the semiconductor layer sequence is grown on a growth substrate in a first step. The growth substrate maybe a sapphire substrate, for example. The semiconductor layer sequence preferably comprises a first semiconductor region of a first conductivity type, a second semiconductor region of a second conductivity type and an active layer arranged therebetween. Preferably, the n-type semiconductor region faces the growth substrate and the p-type semiconductor region faces away from the growth substrate.

In a further method step, a dielectric encapsulation layer is advantageously applied to the semiconductor layer sequence. In particular, the dielectric encapsulation layer is applied to the first semiconductor region facing away from the growth substrate, in particular a p-type semiconductor region. The dielectric encapsulation layer is preferably applied by means of an ALD method and preferably has a thickness of between 5 nm to 100 nm.

According to one embodiment, the dielectric encapsulation layer is initially applied to the entire surface of the semiconductor layer sequence, wherein, in a subsequent method step, an opening is generated in the dielectric encapsulation layer. The generation of the opening is preferably effected in the dielectric encapsulation layer by means of applying a mask layer and a subsequent etching process, in which the mask layer is partially undercut. After the etching process, the mask layer comprises an undercut such that the mask layer and the encapsulation layer form a T-shaped cross-sectional profile (T topping).

According to at least one embodiment, in a further method step, a mirror layer is applied, wherein the mirror layer preferably comprises silver. The mirror layer is preferably applied through the opening in the partially undercut mask layer such that a gap is created between the mirror layer and the dielectric encapsulation layer. This may, for example, be affected by applying the mirror layer by means of a directed coating method, for example, by means of thermal vapor deposition. Since in the process of thermal vapor deposition, the particles of the coating material impinge on the mask layer in a directed manner, in particular substantially perpendicularly, the mirror layer is substantially only applied in the opening of the mask layer, but not in the undercut regions of the mask layer. Thus, a gap between the mirror layer and the dielectric encapsulation layer is created such that the mirror layer does in particular not directly adjoin the dielectric encapsulation layer. The mirror layer is preferably tempered after application to improve the electrical contact to the adjacent semiconductor region.

In a further method step, an electrically conductive protective layer is preferably applied to the mirror layer such that the electrically conductive protective layer covers the surface facing away from the semiconductor layer sequence and the side flanks of the mirror layer. The mirror layer thus is completely covered by the electrically conductive protective layer on the side facing away from the semiconductor layer sequence. This may, for example, be affected by applying the electrically conductive protective layer to the mirror layer by means of an undirected coating method, in particular by sputtering, such that in the coating process, the material of the electrically conductive protective layer is also applied to the regions in which the mask layer is undercut. In particular, the electrically conductive protective layer is applied by the mask layer via which the mirror layer was applied before.

In a subsequent method step, the semiconductor chip is connected to a support substrate. The connection of the semiconductor chip to a support substrate is effected on a side facing away from the growth substrate, for example, by means of a connecting layer, in particular a solder layer. The support substrate may be a semiconductor substrate such as a silicon substrate, for example.

In a subsequent method step, the growth substrate is removed from the semiconductor layer sequence. The removal of the growth substrate may be effected by means of a laser lift-off process, for example.

In a further method step, a mesa structure is generated in the semiconductor layer sequence, thereby exposing the dielectric encapsulation layer in a region next to the semiconductor layer sequence.

In a further method step, the dielectric cover layer is advantageously applied, which covers the region of the dielectric encapsulation layer next to the semiconductor layer sequence and the semiconductor layer sequence at least partially. The transparent dielectric cover layer is preferably at least partially applied by means of an ALD method. In particular, the first partial layer of the transparent dielectric cover layer may be applied by means of an ALD method and a second partial layer by means of vapor deposition or sputtering.

Further advantageous embodiments of the methods result from the description of the optoelectronic semiconductor chip and vice versa.

### BRIEF DESCRIPTION OF THE DRAWINGS

In the following, the invention is explained in more detail by means of exemplary embodiments in conjunction with FIGS. 1 and 2.

FIG. 1 shows a schematic illustration of a cross-section through an optoelectronic semiconductor chip according to an exemplary embodiment, and

FIGS. 2A to 2H show a schematic illustration of a method for producing the optoelectronic semiconductor chip according to the exemplary embodiments using intermediate steps.

### DETAILED DESCRIPTION OF ILLUSTRATIVE EMBODIMENTS

The same or similar elements are referred to with the same reference numerals in the Figures. The illustrated elements and the scales of the elements with respect to each other are not to be considered as drawn to scale.

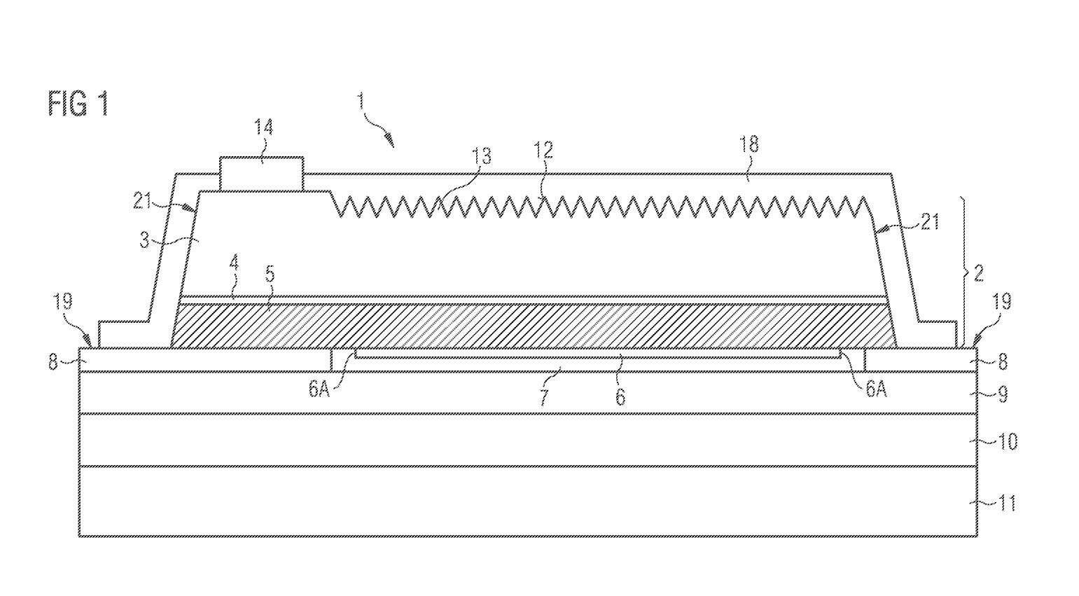

The optoelectronic semiconductor chip 1 schematically shown in cross-section in FIG. 1 comprises a semiconductor layer sequence 2 comprising a first semiconductor region 5 of a first conductivity type and a second semiconductor region 3 of a second conductivity type. Preferably, the first semiconductor region 5 is a p-type semiconductor region and the second semiconductor region 3 an n-type semiconductor region. Between the first semiconductor region 5 and the second semiconductor region 3, an active layer 4 is arranged.

The active layer 4 of the optoelectronic semiconductor chip 1 is preferably an active layer suitable for emitting radiation. The active layer 4 may, for example, be formed as a pn-junction, as a double hetero-structure, as a single quantum well structure or a multiple quantum well structure.

The semiconductor layer sequence 2 of the semiconductor chip 1 is preferably based on a III-V semiconductor compound material, in particular an arsenide, a nitride or phosphide semiconductor compound material. For example, the semiconductor layer sequence 2 may contain InₓAl_{y}Ga_{1-x-y}N, InₓAl_{y}Ga_{1-x-y}P or InₓAl_{y}Ga_{1-x-y} As, each with o≦x≦1, o≦y≦1 and x+y≦1. The III-V semiconductor compound material does not necessarily have to comprise a mathematically exact composition according to one of the formulas specified above. It may rather comprise one or more dopants as well as additional components that do not substantially change the physical properties of the material. For the sake of simplicity, the formulas specified above however only contain the essential components of the crystal lattice, even though these may be partially substituted by small amounts of other substances.

The optoelectronic semiconductor chip 1 comprises a support substrate 11, which is preferably not the same as the growth substrate of the semiconductor layer sequence 2 and is, for example, connected to the semiconductor chip 1 by means of a connecting layer 10, which may in particular be a solder layer made of a metal or metal alloy. The support substrate 11 may alternatively also be produced by means of a galvanic process. Preferably, the support substrate 11 is electrically conductive and serves for electrically contacting the first semiconductor region 5. The support substrate 11 preferably comprises silicon, nickel, copper or molybdenum.

To improve the radiation efficiency of the optoelectronic semiconductor chip 1, a mirror layer 6 is arranged between the semiconductor layer sequence 2 and the support substrate 11. The mirror layer 6 is arranged behind the first semiconductor region 5 on the side facing the support substrate 11 and, in particular, may but against the semiconductor layer sequence 2. It is also possible to have an intermediate layer arranged between the first semiconductor region 5 and the mirror layer 6, for example, a thin adhesion promoting layer (not shown). Between the support substrate 11 and the mirror layer 6, the connecting layer 10, in particular a solder layer made of a metal or metal alloy, and a barrier layer 9 may, for example, be arranged, which barrier layer 9 may be, for example, a Ti, TiW or TiW(N) layer. The barrier layer 9 prevents in particular a diffusion of components of the mirror layer 6 into the connecting layer 10 and vice versa.

The mirror layer 6 contains in particular silver or consists of silver. Silver has a high reflectivity in the visible spectral range and a good electrical conductivity. The mirror layer 6 has on the one hand the function of reflecting radiation emitted by the active layer 4 toward the support substrate 11 to the radiation exit surface 12. On the other hand, the mirror layer 6 also serves to electrically contact the first semiconductor region 5.

For example, the electrical contact with the second semiconductor region 3 is affected by means of a contact 14, which may be formed as a bond pad, for example. The surface of the semiconductor layer sequence 2 forming the radiation exit surface 12 of the semiconductor chip 1 preferably comprises a roughening or a decoupling structure 13 to improve the radiation outcoupling from the semiconductor layer sequence 2.

In the optoelectronic semiconductor chip 1, a dielectric encapsulation layer 8 is advantageously arranged laterally next to the mirror layer 6. The dielectric encapsulation layer 8 is at least partially arranged between the semiconductor layer sequence 2 and the support substrate 11. The semiconductor layer sequence 2 is formed as a mesa structure, for example, by being structured into a desired shape and width by means of an etching process. In particular, the lateral extension of the semiconductor layer sequence 2 is smaller than the lateral extension of the support substrate 11. The dielectric encapsulation layer 8 extends in a lateral direction all the way to a region next to the semiconductor layer sequence 2. In particular, the encapsulation layer 8 has the advantage of protecting the corrosion-sensitive mirror layer 6 from moisture that enters from a lateral direction. Preferably, the dielectric encapsulation layer 8 is an ALD layer, because a layer produced by means of atomic layer deposition has a high density and therefore especially good protection against the entry of moisture.

Preferably, the dielectric encapsulation layer 8 is an Al₂O₃ layer. Preferably, the thickness of the dielectric encapsulation layer is between 5 nm and 100 nm, for example, approximately 40 nm.

In the semiconductor chip 1, a particularly good protection against corrosion is further achieved in that a region of the dielectric encapsulation layer 8 arranged next to the mesa structure and the semiconductor layer sequence 2 are at least partially covered by a transparent dielectric cover layer 18. The transparent dielectric cover layer 18 particularly covers the side flanks 21 of the semiconductor layer sequence 2. In this way, the cover layer 18 protects the semiconductor chip 1 in particular from the entry of moisture in the region in which the side flanks 21 of the semiconductor layer sequence 2 abut the dielectric encapsulation layer 8. In this region, there may otherwise be the risk of moisture diffusing at the interface between the semiconductor layer sequence 2 and the dielectric encapsulation layer 8 toward the mirror layer 6.

The dielectric cover layer 18 preferably covers all regions of the semiconductor layer sequence 2 that do not adjoin a different layer. In particular, the dielectric cover layer 18 covers the side flanks 21 of the semiconductor layer sequence and the radiation exit surface 12. Since part of the dielectric cover layer 18 is applied to the radiation exit surface, the dielectric cover layer is advantageously transparent for the radiation emitted by the active layer 2. On the upper surface of the semiconductor layer sequence 2, there may be provided a cavity in the cover layer 18 for the contact 14 for electrically connecting the second semiconductor region 3.

The dielectric cover layer 18 may be formed of a single layer or of two or more partial layers (not shown). Preferably, at least one partial layer of the dielectric cover layer 18 is an ALD layer. In the case that the dielectric cover layer 18 is formed of multiple partial layers, a first partial layer, which directly abuts the semiconductor layer sequence 2 and the dielectric encapsulation layer 8, is an ALD layer, in particular an Al₂O₃ layer. The dielectric cover layer 18 or at least a first partial layer thereof may therefore be formed in particular of the same material as the dielectric encapsulation layer 8. The thickness of the first partial layer of the dielectric cover layer 18 is, for example, between 5 nm and 100 nm, preferably approximately 40 nm. The dielectric cover layer 18 may comprise a second partial layer, which forms additional protection against the entry of moisture and, furthermore, mechanical protection. The second partial layer may have a greater thickness than the first partial layer and, in particular, may be a silicon oxide layer, for example, a SiO₂ layer. In particular, the second partial layer may have a thickness of between 50 nm and 100 nm.

Even further improved protection of the mirror layer 6 is achieved in that a side of the mirror layer 6 facing the support substrate 11 is covered by an electrically conductive protective layer 7. The electrically conductive protective layer 7is preferably a ZnO layer. The electrically conductive protective layer 7covers the mirror layer 6 advantageously completely including the side flanks 6a of the mirror layer 6. The electrically conductive protective layer 7 has in particular the advantage that it prevents a diffusion of silver from the mirror layer 6 toward the side flanks 21 of the semiconductor layer sequence 2.

On the side of the dielectric encapsulation layer 8 facing the support substrate 11 and the electrically conductive protective layer 7, a barrier layer 9 is advantageously arranged, which reduces in particular a diffusion of components of the connecting layer 10, for example, a solder layer containing gold, into the mirror layer 6. The barrier layer 9 preferably contains a metal compound, which may contain in particular Ti, TiW or TiW(N). The barrier layer 9 has a thickness of between 300 nm and 500 nm, in particular 450 nm, for example.

For example, the connecting layer 10 is a solder layer, which may in particular comprise Au. The connecting layer 10 is, for example, designed as a multi-layer structure which contains, in addition to the solder material such as, for example, gold, one or multiple further sub-layers, which function in particular for improving the adhesion, for improving the wettability, or as diffusion barriers. To this end, one or multiple partial layers may be provided comprising Ti, Pt, Au, Ni and/or Sn, for example.

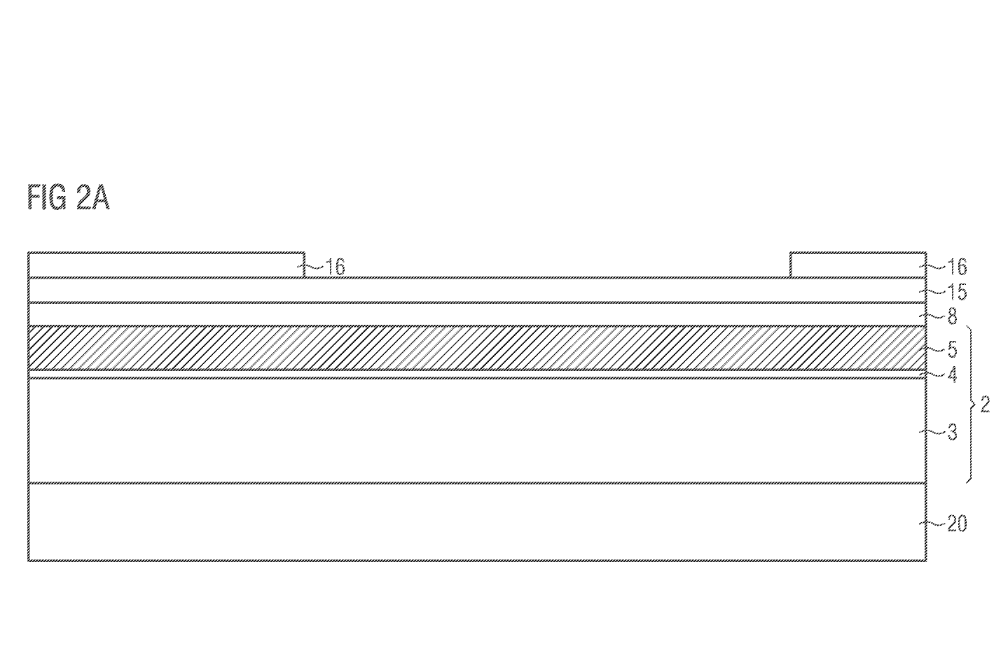

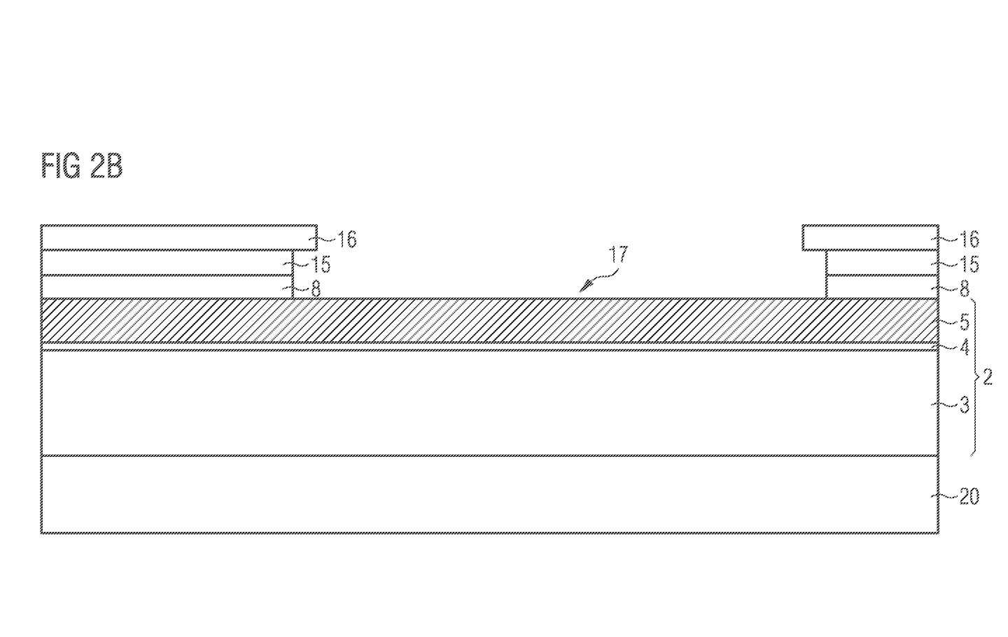

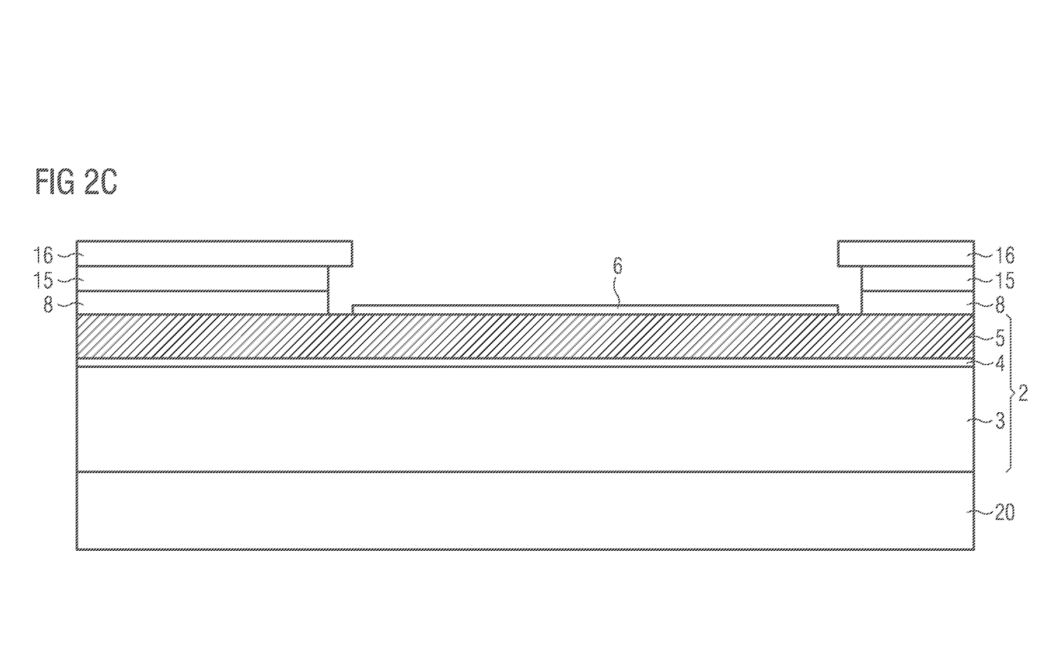

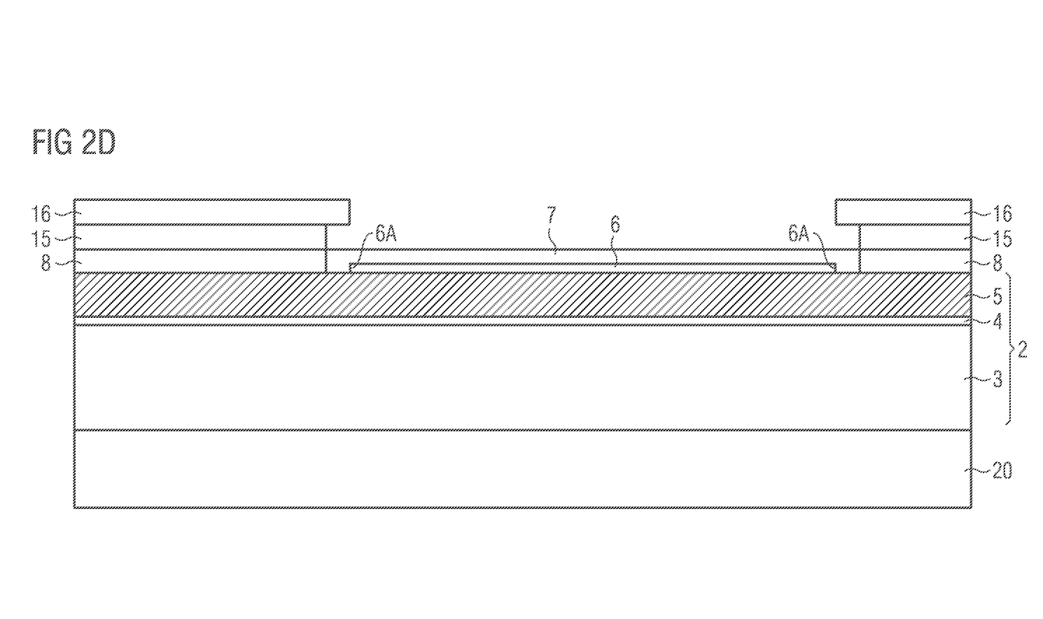

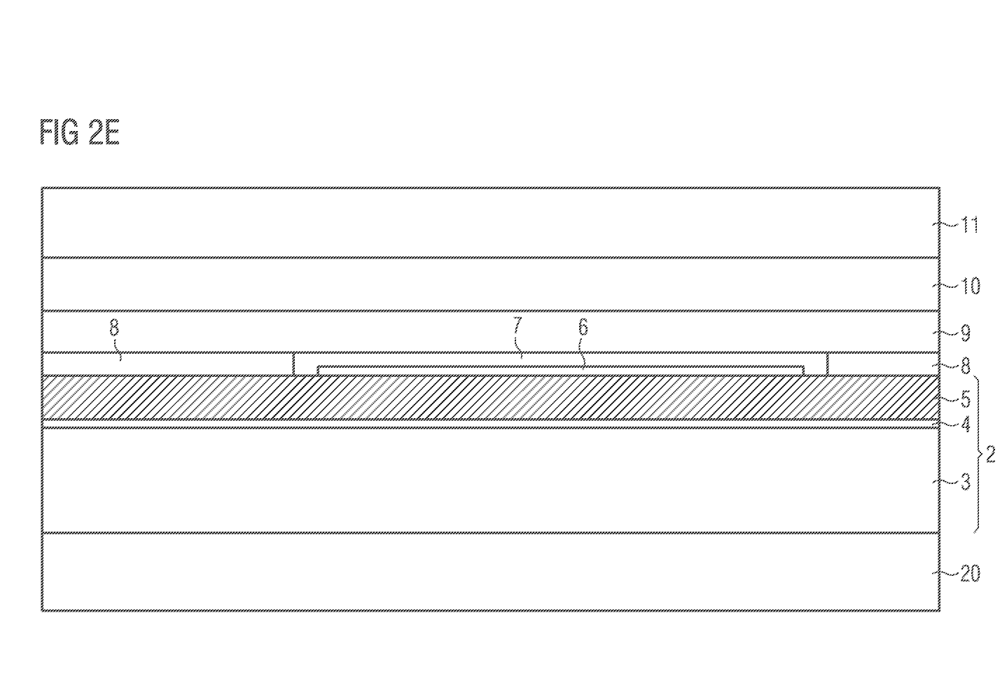

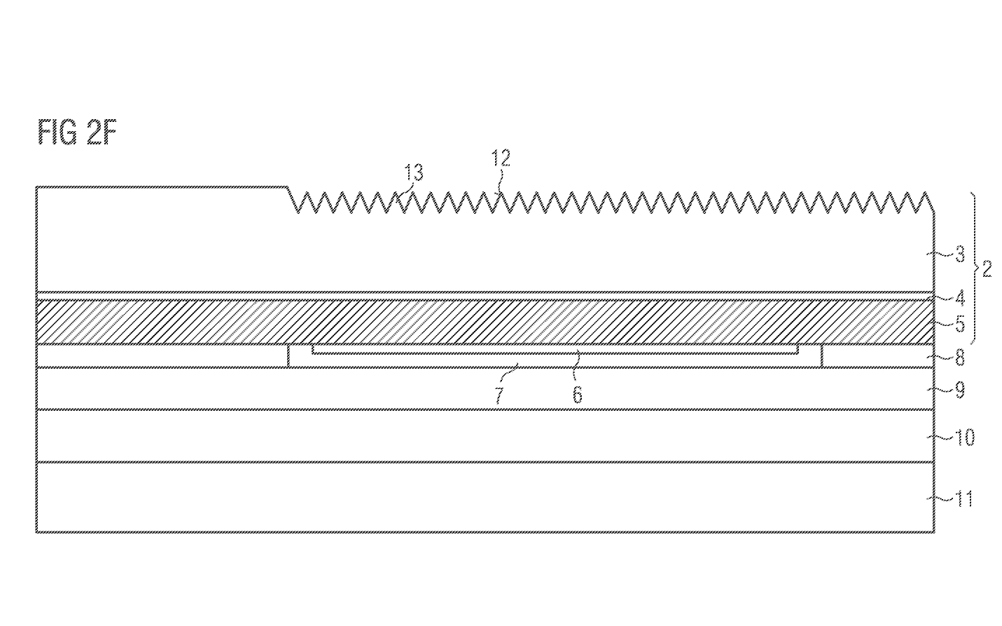

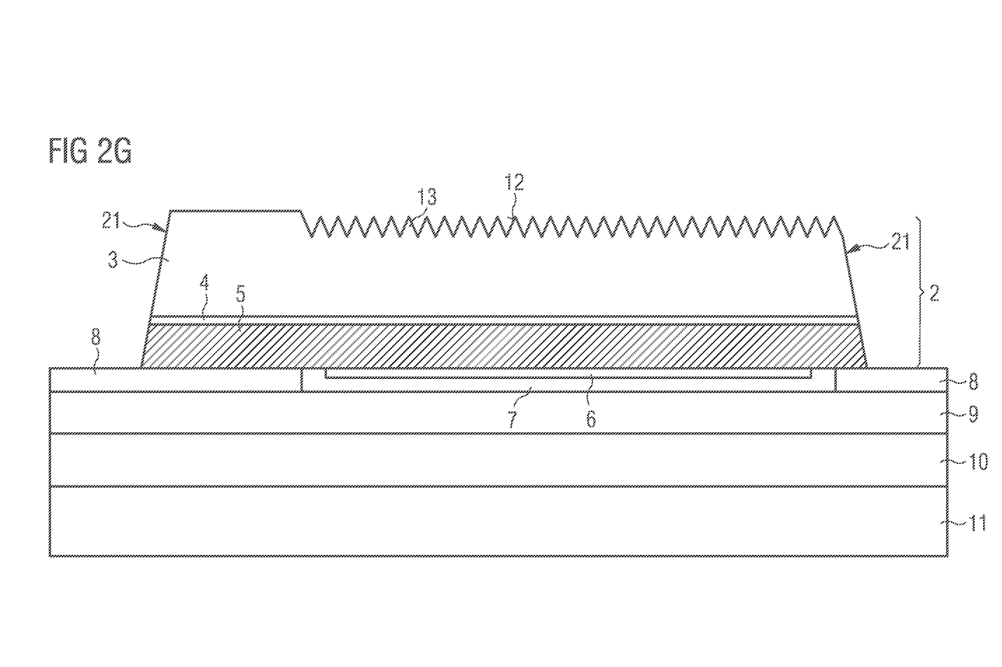

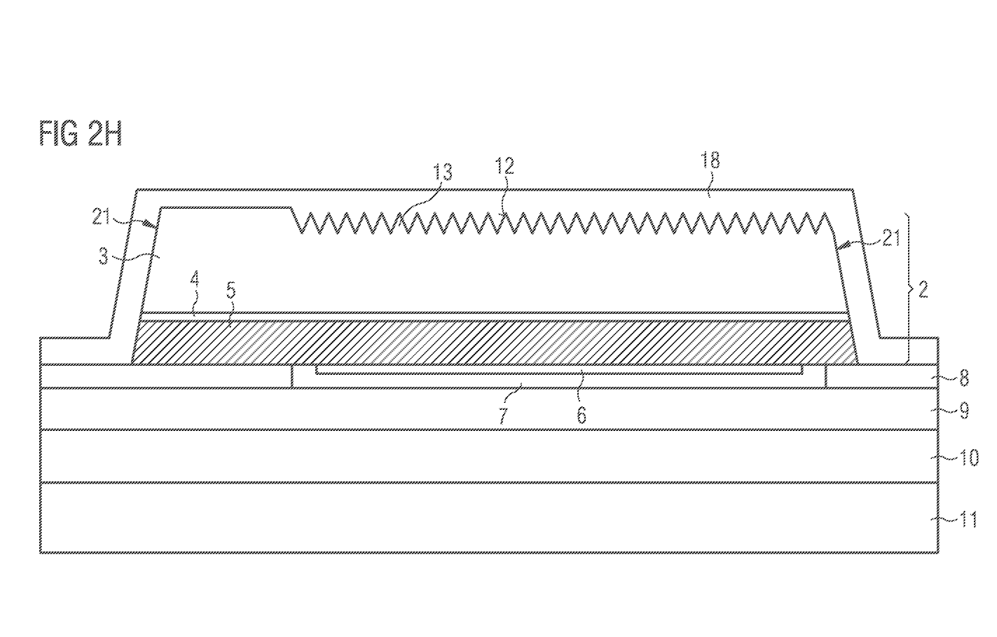

One exemplary embodiment of a method for producing the semiconductor chip 1 of FIG. 1 is explained in the following with reference to FIGS. 2A to 2H.

In the intermediate step of the method shown in FIG. 2a, the semiconductor layer sequence 2 comprising the first semiconductor region 5, the active layer 4 and the second semiconductor region 3 was grown on a growth substrate 20. The growing process is preferably affected epitaxially, in particular by means of MOVPE. The semiconductor layer sequence 2 may contain nitride semiconductor compound materials and the growth substrate 20 may be a sapphire substrate, for example. The first semiconductor region 5 preferably is a p-type semiconductor region and the second semiconductor region 3 preferably is an n-type semiconductor region.

Furthermore, a dielectric encapsulation layer 8 was deposited on the p-type semiconductor region 5 by means of atomic layer deposition (ALD). The dielectric encapsulation layer 8 advantageously has a thickness of approximately 5 nm to 100o nm, for example, 40 nm. The dielectric encapsulation layer 8 has a mask carrier layer 15 and a mask layer 16 applied thereto, wherein the mask layer 16 comprises an opening for applying the mirror layer in a further method step. The mask carrier layer 15 has the function of generating a distance between the mask layer 16 and the dielectric encapsulation layer 8. The mask carrier layer 15 may, for example, be a SiO₂ layer and have a thickness of approximately 50 nm to 100 nm.

In the intermediate step shown in FIG. 2B, an opening 17 was generated in the dielectric encapsulation layer 8 and the mask carrier layer 15 using the mask layer 16 as an etching mask. This can be achieved by means of an etching process, for example, a plasma etching process, and/or an etching process using phosphoric acid (H₃PO4). In the etching process, the mask layer 16 is advantageously partially undercut such as to create a T-shaped cross-sectional profile (T topping). In other words, the mask layer 16 comprises an undercut. The opening generated in the dielectric encapsulation layer 8 during the etching process is therefore slightly larger than the opening in the mask layer 16.

In the intermediate step shown in FIG. 2C, the mirror layer 6 was deposited through the opening in the mask layer 16 onto the p-type semiconductor region 5. The mirror layer 6 is preferably applied by means of a directed coating method, in which the material of the mirror layer 6 impinges the mask layer 16 almost perpendicularly. This is, for example, approximately the case if the mirror layer 6 is applied by thermal vapor deposition at a great distance from the vapor deposition source.

By applying the mirror layer 6 using a directed coating method, the mirror layer 6 is substantially only deposited in the opening of the mask layer 16, however not beneath the undercut regions of the mask layer 16. The side flanks 6a of the mirror layer therefore have a distance to the dielectric encapsulation layer 8. This creates a gap between the mirror layer 6 and the dielectric encapsulation layer 8. The mirror layer 6 preferably is a silver layer. After the application process, a temperature treatment of the silver layer may be performed, in particular at a temperature of more than 200° C. in order to improve the electrical contact between the mirror layer 6 and the p-type semiconductor region 3.

In the intermediate step schematically shown in FIG. 2D, an electrically conductive protective layer 7 was deposited onto the mirror layer 6 through the opening in the mask layer 16. In contrast to the mirror layer 6, the electrically conductive protective layer 7 is applied by means of an undirected coating method, in which the material of the electrically conductive protective layer impinges the mask layer 16 at least partially at oblique incidence angles. Thereby, the electrically conductive protective layer is also applied in the undercut regions of the mask layer 16 and thus extends all the way to the dielectric encapsulation layer 8. In particular, the electrically conductive protective layer 7 also covers the side flanks 6a of the mirror layer 6. In the completed component, this has the advantage of efficiently preventing a diffusion of silver from the mirror layer 6 toward the dielectric encapsulation layer 8. In particular, the electrically conductive protective layer 7 may be a ZnO layer. After applying the electrically conductive protective layer 7, the mask carrier layer 15 and the mask layer 16 are removed. To that end, for example, buffered oxide etch (BOE) may be used.

In the intermediate step shown in FIG. 2E, a barrier layer 9 was applied to the sides of the dielectric encapsulation layer 8 facing away from the semiconductor layer sequence 2 and the electrically conductive protective layer 7. The barrier layer 9 contains, for example, Ti, TiW or TiW(N) and has the function of preventing a diffusion of the material from subsequent metallization layers into the mirror layer and vice versa.

On the side of the barrier layer 9 facing away from the semiconductor layer sequence 2, the semiconductor chip was connected to a support substrate 11 by means of a connecting layer 10. The connecting layer 10 may in particular comprise a solder layer, for example, gold. The connecting layer 10 may be a multilayer system, which may contain, on the side of the barrier layer 9 and/or the side of the support substrate 11, further layers, which improve, for example, the adhesion of the solder layer or the wetting of the solder layer on the components to be connected, wherein the multilayer system may comprise, for example, layers made of Ti, Pt, Au, Ni or Sn. In particular, the support substrate 11 may be electrically conductive and preferably comprises silicon, nickel, copper or molybdenum.

In the intermediate step shown in FIG. 2F, the growth substrate 20 was removed from the semiconductor layer sequence 2. The optoelectronic semiconductor chip 1 is, in comparison to the previous Figures, illustrated rotated by 180°, as the support substrate 11 positioned opposite the original growth substrate 20 now functions as the only support of the semiconductor chip 1. The growth substrate 20, in particular a sapphire substrate, may, for example, be removed from the semiconductor layer sequence 2 by means of a laser lift-off process.

Furthermore, in the intermediate step of FIG. 2F, the now exposed surface of the n-type semiconductor region 3 was provided with a decoupling structure 13. The production of the decoupling structure 13 may in particular be effected by means of an etching process. The decoupling structure 13 improves the radiation decoupling from the radiation emitted by the active layer 4, because the surface of the n-type semiconductor region 5 serves as a radiation exit surface 12 in the completed semiconductor chip.

In the intermediate step shown in FIG. 2G, the semiconductor layer sequence 2 was structured into a mesa structure. The edge areas of the semiconductor layer sequence 2 were removed until the dielectric encapsulation layer 8 in order to produce a semiconductor layer sequence 2 having a desired shape and size. The semiconductor layer sequence 2 designed as a mesa structure has a smaller lateral extension than the support substrate 11. In this step, oblique side flanks 21 may have been produced in the semiconductor layer sequence. The structuring of the semiconductor layer sequence 2 is preferably effected photolithographically, wherein a plasma etching process may be used for etching, for example.

In the further intermediate step shown in FIG. 2H, the dielectric cover layer 18 was applied to the exposed regions of the dielectric encapsulation layer 8 next to the semiconductor layer sequence 2 and to all exposed regions of the semiconductor layer sequence 2. The dielectric cover layer 18 covers in particular the side flanks 21 and the radiation exit surface 12 of the semiconductor layer sequence 2. The dielectric cover layer 18 may be formed as a single layer or multi-layer. The dielectric cover layer 18 may, for example, comprise, as a first partial layer, an Al₂O₃ layer produced by means of ALD and, as a second partial layer, a SiO₂ layer. The two partial layers are, for the sake of simplicity, not shown separately in FIG. 2H. Alternatively or additionally to the SiO₂ layer, the dielectric cover layer may comprise a silicon nitride layer. The silicon nitride layer may, for example, be provided for adjusting the brightness of the radiation emitted by the optoelectronic semiconductor chip.

For completing the optoelectronic semiconductor chip 1 shown in FIG. 1, in a further intermediate step, an opening for a contact 14 may be generated in the dielectric cover layer 18 and a bond pad may, for example, be applied therein. The contact 14 is preferably arranged on a radiation exit surface 12 of the semiconductor chip such that part of the dielectric encapsulation layer 8 is, in a vertical direction, positioned opposite the contact 14 to reduce a current injection into the region of the semiconductor layer sequence 2 beneath the contact 14. Due to the electrically insulating properties of the encapsulation layer 8, this achieves that the generation of radiation beneath the contact 14 is reduced, and thus absorption within the contact 14 is reduced.

Furthermore, when producing several optoelectronic semiconductor chips 1 in a wafer compound, a trench may be generated in the dielectric cover layer 18 between the mesa structures to facilitate the partitioning of the wafer compound into individual semiconductor chips. In the completed semiconductor chip 1, this can be recognized by the fact that the dielectric cover layer 18 is removed in an edge region 19 on the outer side of the semiconductor chip 1.

The invention described herein is not limited by the description of the exemplary embodiments. The invention rather includes each new feature as well as each combination of features, which in particular includes any combination of features in the patent claims, even though the respective feature or combination may not explicitly be specified in the patent claims or exemplary embodiments.

1-14. (canceled)

15. An optoelectronic semiconductor chip comprising:
a support substrate;
a semiconductor layer sequence comprising a first semiconductor region of a first conductivity type, a second semiconductor region of a second conductivity type and an active layer arranged therebetween, wherein the semiconductor layer sequence comprises a mesa structure;
a mirror layer arranged between the support substrate and the semiconductor layer sequence, the mirror layer comprising silver;
a dielectric encapsulation layer arranged at least partly between the semiconductor layer sequence and the support substrate, wherein the encapsulation layer is arranged laterally next to the mirror layer and extends in a lateral direction into a region next to the mesa structure; and
a transparent dielectric cover layer partially covering a region of the encapsulation layer that is arranged next to the mesa structure and the semiconductor layer sequence,
wherein the mirror layer and side flanks of the mirror layer are covered by an electrically conductive protective layer.

16. The optoelectronic semiconductor chip according to claim 15, wherein the protective layer contains ZnO.

17. The optoelectronic semiconductor chip according to claim 15, wherein the encapsulation layer and/or the cover layer is an ALD layer.

18. The optoelectronic semiconductor chip according to claim 15, wherein the encapsulation layer comprises Al₂O₃.

19. The optoelectronic semiconductor chip according to claim 15, wherein the cover layer comprises Al₂O₃ and/or SiO₂.

20. The optoelectronic semiconductor chip according to claim 15, further comprising a contact arranged on a radiation exit surface of the semiconductor chip, wherein a part of the dielectric encapsulation layer is, viewed in a vertical direction, arranged opposite the contact to reduce a current injection into the region of the semiconductor layer sequence beneath the contact.

21. A method for producing an optoelectronic semiconductor chip, the method comprising:
producing a semiconductor layer sequence on a growth substrate;
applying a dielectric encapsulation layer on the semiconductor layer sequence;
generating an opening in the encapsulation layer;
applying a mirror layer in the opening of the encapsulation layer, wherein the mirror layer comprises silver;
applying an electrically conductive protective layer on the mirror layer, wherein the protective layer covers the mirror layer including side flanks of the mirror layer,
connecting the semiconductor chip with a support substrate;
removing the growth substrate;
generating a mesa structure in the semiconductor layer sequence, thereby exposing a region of the encapsulation layer that is arranged next to the semiconductor layer sequence; and
applying a transparent dielectric cover layer partially covering the region of the encapsulation layer that is arranged next to the semiconductor layer sequence and the semiconductor layer sequence.

22. The method according to claim 21, wherein generating the opening in the encapsulation layer comprises applying a mask layer and subsequently etching the encapsulation layer, in which the mask layer is partially undercut.

23. The method according to claim 22, wherein the mirror layer is applied in the opening in the partially undercut mask layer such that a gap between the mirror layer and the encapsulation layer is created.

24. The method according to claim 23, wherein, after applying the mirror layer, the electrically conductive protective layer is applied to the mirror layer, wherein the gap is closed upon application of the protective layer.

25. The method according to claim 21, wherein the encapsulation layer is applied using an ALD method.

26. The method according to claim 21, wherein the encapsulation layer comprises Al₂O₃.

27. The method according to claim 21, wherein the cover layer is applied at least partially by using an ALD method.

28. The method according to claim 21, wherein the cover layer comprises Al₂O₃ and/or SiO₂.

29. A method for producing an optoelectronic semiconductor chip, the method comprising:
producing a semiconductor layer sequence on a growth substrate;
applying a dielectric encapsulation layer on the semiconductor layer sequence;
generating an opening in the encapsulation layer;
applying a mirror layer in the opening of the encapsulation layer, wherein the mirror layer comprises silver;
applying an electrically conductive protective layer on the mirror layer, wherein the protective layer covers the mirror layer including side flanks of the mirror layer;
connecting the semiconductor chip with a support substrate;
removing the growth substrate;
generating a mesa structure in the semiconductor layer sequence, thereby exposing a region of the encapsulation layer that is arranged next to the semiconductor layer sequence; and
applying a transparent dielectric cover layer at least partially covering the region of the encapsulation layer that is arranged next to the semiconductor layer sequence and the semiconductor layer sequence,
wherein generating the opening in the encapsulation layer comprises applying a mask layer and subsequently etching the encapsulation layer, in which the mask layer is partially undercut, and
wherein the mirror layer is applied in the opening in the partially undercut mask layer such that a gap between the mirror layer and the encapsulation layer is created.
